(19) United States
(12) Patent Application Publication
(10) Pub. No.: US 2021/0273185 A1
(43) Pub. Date: Sep. 2, 2021

(54) HOLE TRANSPORT LAYER COMPRISING THERMALLY CONDUCTIVE INORGANIC STRUCTURE, PEROVSKITE SOLAR CELL COMPRISING SAME, AND METHOD OF MANUFACTURING SAME

(71) Applicant: POSTECH Research and Business Development Foundation, Pohang-si (KR)

(72) Inventors: Taiho PARK, Pohang-si (KR); Kyoungwon CHOI, Pohang-si (KR)

(21) Appl. No.: 17/075,952

(22) Filed: Oct. 21, 2020

(30) Foreign Application Priority Data
Mar. 2, 2020 (KR) 10-2020-0025866

(51) Int. Cl. H01L 51/42; H01L 51/44

(52) U.S. Cl. CPC H01L 51/4213; H01L 51/442

(57) ABSTRACT

Disclosed are a hole transport layer including a thermally conductive inorganic structure, a perovskite solar cell including the same, and a method of manufacturing the same. The hole transport layer includes a thermally conductive inorganic structure including a plurality of nanoparticles and having pores surrounded by the nanoparticles and a hole transport organic material located in the pores, in which the nanoparticles include at least one inorganic material selected from the group consisting of a metal oxide and a metal nitride, whereby the hole transport layer not only effectively dissipates heat from the inside of devices but also avoids interfering with hole transport when applied to devices, thereby maintaining the high efficiency of solar cells and also greatly improving thermal and long-term stability thereof.

### CROSS REFERENCE TO RELATED APPLICATION

The present application claims priority based on Korean Patent Application No. 10-2020-0025866, filed on Mar. 2, 2020, the entire content of which is incorporated herein for all purposes by this reference.

### BACKGROUND OF THE INVENTION

### 1. Technical Field

The present invention relates to a hole transport layer including a thermally conductive inorganic structure, a perovskite solar cell including the same, and a method of manufacturing the same. More particularly, the present invention relates to a hole transport layer, in which the hole transport layer includes a thermally conductive inorganic structure and a hole transport organic material and thus not only effectively dissipates heat from the inside of devices but also avoids interfering with hole transport when applied to devices, thereby maintaining the high efficiency of solar cells and also greatly improving thermal and long-term stability thereof, a perovskite solar cell including the same, and a method of manufacturing the same.

### 2. Description of the Related Art

Organic-inorganic hybrid solar cells, having high photoelectric conversion efficiency, are receiving attention as next-generation solar cells. The photoactive layer of an organic-inorganic hybrid solar cell is formed of perovskite showing the ABX₃ lattice structure, and exhibits various advantages such as a high extinction coefficient and superior charge transport properties. In particular, in order to achieve a high-efficiency device, recently, several types of materials are mixed and used, rather than using a single material, at the ‘A’ and ‘B’ sites in ABX₃, and based thereon, recent perovskite solar cells have achieved high photoelectric conversion efficiency exceeding 25%. However, due to the low stability of perovskite materials, which undergo decomposition in the presence of external stimuli that cannot be avoided in operating environments such as water, heat, light and the like, it is still difficult to expect commercialization thereof.

A perovskite solar cell that is most commonly used is configured to include a transparent electrode/electron transport layer/perovskite/hole transport layer/metal electrode, and a p-type organic material (monomer or polymer) and an inorganic material are mainly used for the hole transport layer. During the operation of the perovskite solar cell, sunlight is radiated onto the transparent electrode and the photoactive layer absorbs light to thus generate an electric charge. Here, the temperature of the perovskite layer, which is the photoactive layer, is very high compared to other layers, and thus, in order to attain thermal stability of the device, it is necessary to effectively dissipate heat generated inside, and the hole transport layer in contact with the atmosphere is regarded as the most important layer for heat dissipation.

However, Spiro-OMeTAD and conductive polymer materials, which are used to achieve the high efficiency of existing perovskite solar cells, have low thermal conductivity due to the nature of the material, making effective heat dissipation impossible. Therefore, in order to realize both high efficiency and high stability of perovskite solar cells, it is required to develop materials that simultaneously ensure heat dissipation and superior charge transport.

### SUMMARY OF THE INVENTION

Accordingly, the present invention has been made keeping in mind the problems encountered in the related art, and an objective of the present invention is to provide a hole transport layer having improved thermal properties and durability.

Another objective of the present invention is to provide a hole transport layer, which may prevent problems (water, high temperatures and the like) that cause performance degradation of perovskite solar cells, thus ensuring the high efficiency of devices and improving the stability thereof at the same time, and a perovskite solar cell including the hole transport layer.

Still another objective of the present invention is to provide a hole transport layer capable of effectively suppressing charge recombination at the interface thereof to thereby increase the open-circuit voltage, and forming and maintaining the morphology thereof.

An aspect of the present invention provides a hole transport layer, including: a thermally conductive inorganic structure including a plurality of nanoparticles and having pores surrounded by the nanoparticles; and a hole transport organic material located in the pores, in which the nanoparticles include at least one inorganic material selected from the group consisting of a metal oxide and a metal nitride.

Also, a portion of the plurality of nanoparticles may be located on a top surface of the hole transport layer, a further portion of the plurality of nanoparticles may be located on a bottom surface of the hole transport layer, and still a further portion of the plurality of nanoparticles may form a connection between the nanoparticles located on the top surface and the nanoparticles located on the bottom surface.

Also, the connection may be a contact connection or a thermal connection.

Also, a portion of the hole transport organic material may be located on the top surface of the hole transport layer, a further portion of the hole transport organic material may be located on the bottom surface of the hole transport layer, and still a further portion of the hole transport organic material may form a connection between the hole transport organic material located on the top surface and the hole transport organic material located on the bottom surface.

Also, the connection may be a contact connection or a thermal connection.

Also, the nanoparticles may have a diameter of 10 to 50 nm, and the ratio d_{HTL}/d_{NP} of the thickness d_{HTL} of the hole transport layer relative to the diameter d_{NP} of the nanoparticles may be 3 to 5.

Also, the inorganic material may have a HOMO (highest occupied molecular orbital) energy level less than −5.6 eV and a LUMO (lowest unoccupied molecular orbital) energy level greater than −3.9 eV.

Also, the inorganic material may include at least one selected from the group consisting of Al₂O₃, MgO, BN, AlN, SiO₂, Si₃N₄, and SiC.

Also, the hole transport organic material may include at least one selected from the group consisting of 2,2′,7,7′-tetrakis-(N,N-di-4-methoxyphenylamino)-9,9′-spirobifluorene (Spiro-OMeTAD), poly[bis(4-phenyl)(2,4,6-trimethylphenyl)amine] (PTAA), poly(3-hexylthiophene-2,5-diyl) (P3HT), poly(3-alkylthiophene) (P3AT), poly(3-octylthiophene-2,5-diyl) (P30T), poly(3,4-ethylenedioxythiophene)-poly(styrenesulfonate) (PEDOT:PSS), poly{4,7-bis(5-bromothiophen-2-yl)-5-(decyloxy)-6-ethoxybenzo[c][1,2,5]thiadiazole} (PBT), poly{(4,8-bis((2-butyloctyl)oxy)benzo[1,2-b:4,5-b′]dithiophene-2,6-diyl)bis(trimethylstannane)} (PBDT), and poly(BT)-(BDT).

Also, the hole transport organic material may be doped with a dopant, and the dopant may include at least one selected from the group consisting of Li-TFSI, Co(II) PF₆, 4-tert-butyl pyridine (tBP), AgTFSI, and CuI.

Another aspect of the present invention provides a perovskite solar cell, including: a first electrode; an electron transport layer formed on the first electrode; a photoactive layer formed on the electron transport layer and including a perovskite material; the hole transport layer formed on the photoactive layer; and a second electrode formed on the hole transport layer.

Also, the first electrode may include at least one selected from the group consisting of fluorine tin oxide (FTO), indium tin oxide (ITO), indium zinc oxide (IZO), indium zinc tin oxide (IZTO), aluminum zinc oxide (AZO), indium-tin-oxide/silver/indium-tin-oxide (ITO-Ag-ITO), indium-zinc-oxide/silver/indium-zinc-oxide (IZO-Ag-IZO), indium-zinc-tin-oxide/silver/indium-zinc-tin-oxide (IZTO-Ag-IZTO), and aluminum-zinc-oxide/silver/aluminum-zinc-oxide (AZO-Ag-AZO).

Also, the electron transport layer may include at least one selected from the group consisting of SnO₂, ZnO, TiO₂, Al₂O₃, MgO, Fe₂O₃, WO₃, In₂O₃, BaTiO₃, BaSnO₃, and ZrO₃.

Also, the perovskite material may include at least one selected from the group consisting of CH₃NH₃PbI₃₋ₓClₓ, (in which x is a real number satisfying 0≤x≤3), CH₃NH₃PbI₃₋ₓBrₓ (in which x is a real number satisfying 0≤x≤3), CH₃NH₃PbCl₃₋ₓBrₓ (in which x is a real number satisfying 0≤x≤3), CH₃NH₃PbI₃₋ₓFₓ (in which x is a real number satisfying 0≤x≤3), NH₂CH═NH₂PbI₃₋ₓClₓ, (in which x is a real number satisfying 0≤x≤3), NH₂CH═NH₂PbI₃₋ₓBrₓ (in which x is a real number satisfying 0≤x≤3), NH₂CH═NH₂PbCl₃₋ₓBrₓ (in which x is a real number satisfying 0≤x≤3), NH₂CH═NH₂PbI₃₋ₓFₓ (in which x is a real number satisfying 0≤x≤3), and Csₖ(NH₂CH═NH₂PbI₃)₍₁₋ₖ₋ₓ₎(CH₃NH₃PbBr₃)ₓ (in which k is a real number satisfying 0≥k≤0.3 and x is a real number satisfying 0≤x≤1−k).

Also, the second electrode may include at least one selected from the group consisting of Ag, Au, Al, Fe, Cu, Cr, W, Mo, Zn, Ni, Pt, Pd, Co, In, Mn, Si, Ta, Ti, Sn, Pb, V, Ru, Ir, Zr, Rh, and Mg.

Still another aspect of the present invention provides a method of manufacturing a hole transport layer, including: (1) forming a thermally conductive inorganic structure including a plurality of nanoparticles and having pores surrounded by the nanoparticles by performing coating with a solution including the nanoparticles and performing drying; and (2) forming a hole transport layer including a hole transport organic material located in the pores by performing coating with a solution including the hole transport organic material on the thermally conductive inorganic structure and performing drying, in which the nanoparticles include at least one inorganic material selected from the group consisting of a metal oxide and a metal nitride.

Also, the coating in step (2) enables the pores to be impregnated with the solution including the hole transport organic material.

Also, the coating in steps (1) and (2) may be performed through at least one process selected from the group consisting of spin coating, spray coating, chemical vapor deposition, and atomic layer deposition.

Also, in step (1), the solution including the nanoparticles may include 0.1 to 3 wt % of the nanoparticles.

Yet another aspect of the present invention provides a method of manufacturing a perovskite solar cell, including: (a) forming an electron transport layer on a first electrode; (b) performing coating with a solution including a perovskite precursor on the electron transport layer; (c) forming a photoactive layer including a perovskite material by heat-treating the perovskite precursor coating layer formed on the electron transport layer; (d) forming a thermally conductive inorganic structure including a plurality of nanoparticles and having pores surrounded by the nanoparticles by performing coating with a solution including the nanoparticles on the photoactive layer; (e) forming a hole transport layer including a hole transport organic material located in the pores by performing coating with a solution including the hole transport organic material on the thermally conductive inorganic structure; and (f) forming a second electrode on the hole transport layer, in which the nanoparticles include at least one inorganic material selected from the group consisting of a metal oxide and a metal nitride.

According to the present invention, a hole transport layer includes an inorganic structure and is thereby capable of improving thermal properties and durability.

Also, a hole transport layer including an inorganic structure is provided, and is thereby capable of preventing problems (water, high temperatures and the like) that cause performance degradation of perovskite solar cells, thus ensuring the high efficiency of devices and improving the stability thereof at the same time.

Also, the use of the inorganic structure made of an appropriate amount of nanoparticles enables open-circuit voltage to increase by effectively suppressing a recombination phenomenon at the interface because of the optimized insulating properties, and moreover, the inorganic structure can serve as a porous support, thereby making it possible to form and maintain the morphology of the organic hole transport material.

### BRIEF DESCRIPTION OF DRAWINGS

Since these drawings are for reference in describing exemplary embodiments of the present invention, the technical spirit of the present invention should not be construed as being limited to the accompanying drawings, in which:

FIG. 1 schematically shows a hole transport layer and a perovskite solar cell according to an embodiment of the present invention;

FIG. 2 shows the temperature over time of each layer of a conventional perovskite solar cell upon light irradiation;

FIG. 3 shows the thermal conductivity of the hole transport layer in the perovskite solar cells manufactured in Examples 1-1 to 4-3;

FIG. 4A shows the results of comparison of the cooling rate of the hole transport layer in the perovskite solar cells of Examples 1-1 to 2-3 and Comparative Example 1;

FIG. 4B shows the results of comparison of the cooling rate of the hole transport layer in the perovskite solar cells of Examples 3-1 to 4-3 and Comparative Example 1;

FIG. 5A shows the stability over time when not encapsulated at 25° C. and 25% relative humidity in Examples 1-3, 2-3, 3-3 and 4-3 and Comparative Example 1; and

FIG. 5B shows the stability over time when not encapsulated at 85° C. and 85% relative humidity in Examples 1-3, 2-3, 3-3 and 4-3 and Comparative Example 1.

### DESCRIPTION OF SPECIFIC EMBODIMENTS

Hereinafter, exemplary embodiments of the present invention are described in detail with reference to the appended drawings so as to be easily performed by a person having ordinary skill in the art.

However, the following description does not limit the present invention to specific embodiments, and in the description of the present invention, detailed descriptions of related known techniques incorporated herein will be omitted when the same may make the gist of the present invention unclear.

The terms herein are used to explain specific embodiments, and are not intended to limit the present invention. Unless otherwise stated, a singular expression includes a plural expression. In the present application, the terms “comprise”, “include” or “have” are used to designate the presence of features, numbers, steps, operations, elements, or combinations thereof described in the specification, and should be understood as not excluding the presence or additional possible presence of one or more different features, numbers, steps, operations, elements, or combinations thereof.

As used herein, the terms “first”, “second”, etc. may be used to describe various elements, but these elements are not to be limited by these terms. These terms are only used to distinguish one element from another. For example, a first element may be termed a second element, and similarly, a second element may be termed a first element, without departing from the scope of the present invention.

Further, it will be understood that when an element is referred to as being “formed” or “stacked” on another element, it can be formed or stacked so as to be directly attached to all surfaces or to one surface of the other element, or intervening elements may be present therebetween.

Hereinafter, a detailed description will be given of a hole transport layer including a thermally conductive inorganic structure, a perovskite solar cell including the same, and a method of manufacturing the same according to the present invention, which is set forth to illustrate but is not to be construed as limiting the present invention, and the present invention is defined only by the accompanying claims.

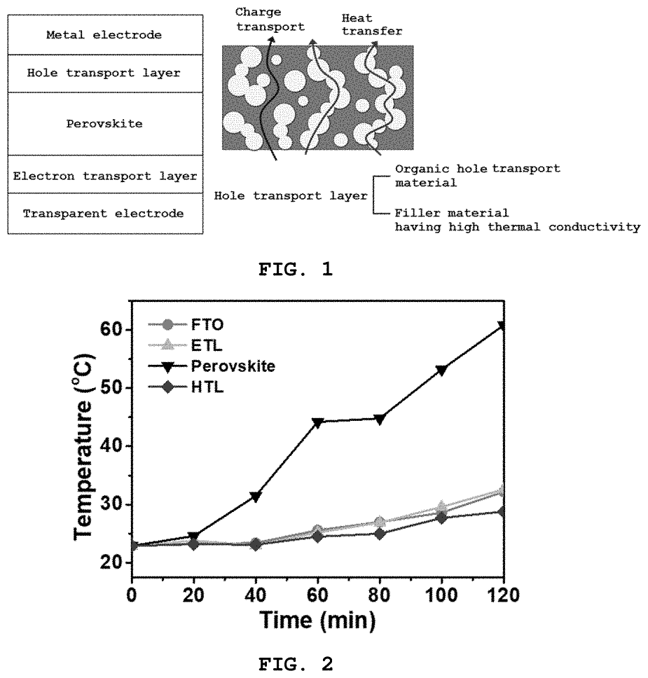

FIG. 1 schematically shows a hole transport layer and a perovskite solar cell according to an embodiment of the present invention.

With reference to FIG. 1, the present invention pertains to a hole transport layer including a thermally conductive inorganic structure including a plurality of nanoparticles and having pores surrounded by the nanoparticles and a hole transport organic material located in the pores, in which the nanoparticles include at least one inorganic material selected from the group consisting of a metal oxide and a metal nitride.

Specifically, the hole transport layer includes an inorganic structure, thereby exhibiting a heat dissipation effect of removing heat from the photoactive layer (perovskite), the temperature of which rises during the operation of the solar cell. Moreover, the hole transport layer blocks the introduction of water and oxygen from the outside, suppresses the process in which holes travel back to the photoactive layer (perovskite) and recombine, and prevents the morphology of the hole transport organic material from changing at a high temperature.

Also, a portion of the plurality of nanoparticles may be located on the top surface of the hole transport layer, a further portion of the plurality of nanoparticles may be located on the bottom surface of the hole transport layer, and still a further portion of the plurality of nanoparticles may form a connection between the nanoparticles located on the top surface and the nanoparticles located on the bottom surface.

Here, the connection may be a contact connection or a thermal connection.

Specifically, an inorganic structure pathway formed by the nanoparticles may be formed inside the hole transport layer, and heat generated in the photoactive layer (perovskite) may be dissipated via the inorganic structure pathway.

Also, a portion of the hole transport organic material may be located on the top surface of the hole transport layer, a further portion of the hole transport organic material may be located on the bottom surface of the hole transport layer, and still a further portion of the hole transport organic material may form a connection between the hole transport organic material located on the top surface and the hole transport organic material located on the bottom surface.

Here, the connection may be a contact connection or a thermal connection.

Specifically, a hole transport organic material pathway formed by the hole transport organic material may be formed inside the hole transport layer, and holes may move via the hole transport organic material pathway.

The diameter of the nanoparticles may be 10 to 50 nm. If the diameter of the nanoparticles is less than 10 nm, it is difficult to impregnate empty voids, formed by connecting the nanoparticles to each other, with the hole transport organic material, which is undesirable. On the other hand, if the diameter thereof exceeds 50 nm, the nanoparticles are not uniformly dispersed in the hole transport layer, thus interfering with the flow of charges, which is undesirable.

Also, the ratio d_{HTL}/d_{NP} of the thickness d_{HTL} of the hole transport layer relative to the diameter d_{NP} of the nanoparticles may be 3 to 5. If the ratio thereof is less than 3, the inner pathway made of the nanoparticles is not well formed, making it difficult to exhibit a heat dissipation effect, which is undesirable. On the other hand, if the ratio thereof exceeds 5, a decrease in charge transport capability and an increase in resistance become severe due to the formation of a thick hole transport layer, which is undesirable in view of solar-cell efficiency.

Also, the HOMO (highest occupied molecular orbital) energy level of the inorganic material may be less than −5.6 eV, and the LUMO (lowest unoccupied molecular orbital) energy level thereof may be greater than −3.9 eV.

Specifically, it is preferable to use an insulator that is nonconductive due to a large energy band gap. In the case of using, as the inorganic material, a conductor or a semiconductor, rather than the insulator, the holes travel back to the photoactive layer (perovskite) and recombine with electrons, which is undesirable.

Also, the inorganic material may include at least one selected from the group consisting of Al₂O₃, MgO, BN, SiO₂, Si₃N₄, and SiC, and preferably includes at least one selected from the group consisting of Al₂O₃ and MgO. Most preferably, Al₂O₃ is used.

Also, the hole transport organic material may include at least one selected from the group consisting of 2,2′,7,7′-tetrakis-(N,N-di-4-methoxyphenylamino)-9,9′-spirobifluorene (Spiro-OMeTAD), poly[bis(4-phenyl)(2,4,6-trimethylphenyl)amine] (PTAA), poly(3-hexylthiophene-2,5-diyl) (P3HT), poly(3-alkylthiophene) (P3AT), poly(3-octylthiophene-2,5-diyl) (P30T), poly(3,4-ethylenedioxythiophene)-poly(styrenesulfonate) (PEDOT:PSS), poly{4,7-bis(5-bromothiophen-2-yl)-5-(decyloxy)-6-ethoxybenzo[c][1,2,5]thiadiazole} (PBT), poly{(4,8-bis((2-butyloctyl)oxy)benzo[1,2-b:4,5-b′]dithiophene-2,6-diyl)bis(trimethylstannane)} (PBDT), and poly(BT)-(BDT), and preferably includes Spiro-OMeTAD.

Also, the hole transport organic material may be doped with a dopant, and the dopant may include at least one selected from the group consisting of Li-TFSI, Co(II) PF₆, 4-tert-butyl pyridine (tBP), AgTFSI, and CuI, and preferably includes at least one selected from the group consisting of Li-TFSI, Co(II) PF₆, and 4-tert-butyl pyridine.

Also, the hole transport layer described above may be used for the hole transport layer of a perovskite solar cell.

In addition, the present invention pertains to a perovskite solar cell including a first electrode, an electron transport layer formed on the first electrode, a photoactive layer formed on the electron transport layer and including a perovskite material, the aforementioned hole transport layer formed on the photoactive layer, and a second electrode formed on the hole transport layer.

Since the hole transport layer includes an inorganic structure, problems (water, high temperatures and the like) that cause performance degradation of the perovskite may be prevented, thus ensuring high efficiency of the device and improving the stability thereof at the same time.

Also, the first electrode may include at least one selected from the group consisting of fluorine tin oxide (FTO), indium tin oxide (ITO), indium zinc oxide (IZO), indium zinc tin oxide (IZTO), aluminum zinc oxide (AZO), indium-tin-oxide/silver/indium-tin-oxide (ITO-Ag-ITO), indium-zinc-oxide/silver/indium-zinc-oxide (IZO-Ag-IZO), indium-zinc-tin-oxide/silver/indium-zinc-tin-oxide (IZTO-Ag-IZTO), and aluminum-zinc-oxide/silver/aluminum-zinc-oxide (AZO-Ag-AZO), and preferably includes fluorine tin oxide (FTO).

Also, the electron transport layer may include at least one selected from the group consisting of SnO₂, ZnO, TiO₂, Al₂O₃, MgO, Fe₂O₃, WO₃, In₂O₃, BaTiO₃, BaSnO₃, and ZrO₃, and preferably includes SnO₂.

Also, the perovskite material may include at least one selected from the group consisting of CH₃NH₃PbI₃₋ₓClₓ, (in which x is a real number satisfying 0≤x≤3), CH₃NH₃PbI₃₋ₓBrₓ (in which x is a real number satisfying 0≤x≤3), CH₃NH₃PbCl₃₋ₓBrₓ (in which x is a real number satisfying 0≤x≤3), CH₃NH₃PbI₃₋ₓFₓ (in which x is a real number satisfying 0≤x≤3), NH₂CH═NH₂PbI₃₋ₓClₓ (in which x is a real number satisfying 0≤x≤3), NH₂CH═NH₂PbI₃₋ₓBrₓ (in which x is a real number satisfying 0≤x≤3), NH₂CH═NH₂PbCl₃₋ₓBrₓ (in which x is a real number satisfying 0≤x≤3), NH₂CH═NH₂PbI₃₋ₓFₓ (in which x is a real number satisfying 0≤x≤3), and Csₖ(NH₂CH═NH₂PbI₃)₍₁₋ₖ₋ₓ₎(CH₃NH₃PbBr₃)ₓ (in which k is a real number satisfying 0≥k≤0.3 and x is a real number satisfying 0≤x≤1-k), and preferably includes Csₖ(NH₂CH═NH₂PbI₃)₍₁₋ₖ₋ₓ₎(CH₃NH₃PbBr₃)ₓ (in which k is a real number satisfying 0≤k≤0.3 and x is a real number satisfying 0≤x≤1−k). More preferably, Cs_{0.05} (NH₂CH═NH₂PbI₃)_{0.95-x} (CH₃NH₃PbBr₃)ₓ (in which x is a real number satisfying 0≤x≤0.95 is used, and even more preferably, Cs_{0.05} (NH₂CH═NH₂PbI₃)_{0.79} (CH₃NH₃PbBr₂)_{0.16} is used.

Also, the second electrode may include at least one selected from the group consisting of Ag, Au, Al, Fe, Cu, Cr, W, Mo, Zn, Ni, Pt, Pd, Co, In, Mn, Si, Ta, Ti, Sn, Pb, V, Ru, Ir, Zr, Rh, and Mg, and preferably includes Au.

In addition, the present invention pertains to a method of manufacturing a hole transport layer including (1) forming a thermally conductive inorganic structure including a plurality of nanoparticles and having pores surrounded by the nanoparticles by performing coating with a solution including the nanoparticles and performing drying, and (2) forming a hole transport layer including a hole transport organic material located in the pores by performing coating with a solution including the hole transport organic material on the thermally conductive inorganic structure and performing drying, in which the nanoparticles include at least one inorganic material selected from the group consisting of a metal oxide and a metal nitride.

Here, the coating in step (2) enables the pores to be impregnated with the solution including the hole transport organic material.

Also, the coating in steps (1) and (2) may be performed through at least one process selected from the group consisting of spin coating, spray coating, chemical vapor deposition, and atomic layer deposition, and is preferably performed through spin coating.

When the coating in step (2) is performed through spin coating, the pores may be filled by applying the hole transport material on the porous structure formed in step (1), and the impregnated layer may be formed by removing the remaining hole transport material through a spin process.

Also, in step (1), the solution including the nanoparticles may include the nanoparticles in an amount of 0.1 to 3 wt %, preferably 0.1 to 2 wt %, more preferably 0.3 to 1.5 wt %, and even more preferably 0.5 to 1 wt %. If the amount of the nanoparticles is less than 0.1 wt %, it is difficult to form a heat transfer pathway inside the hole transport layer, which is undesirable. On the other hand, if the amount thereof exceeds 3 wt %, it is difficult to form the charge transport pathway of the hole transport organic material, which is undesirable.

In addition, the present invention pertains to a method of manufacturing a perovskite solar cell including (a) forming an electron transport layer on a first electrode, (b) performing coating with a solution including a perovskite precursor on the electron transport layer, (c) forming a photoactive layer including a perovskite material by heat-treating a perovskite precursor coating layer formed on the electron transport layer, (d) forming a thermally conductive inorganic structure including a plurality of nanoparticles and having pores surrounded by the nanoparticles by performing coating with a solution including the nanoparticles on the photoactive layer, (e) forming a hole transport layer including a hole transport organic material located in the pores by performing coating with a solution including the hole transport organic material on the thermally conductive inorganic structure, and (f) forming a second electrode on the hole transport layer, in which the nanoparticles include at least one inorganic material selected from the group consisting of a metal oxide and a metal nitride.

### EXAMPLES

A better understanding of the present invention may be obtained through the following examples. However, these examples are merely set forth to illustrate the present invention, and are not to be construed as limiting the scope of the present invention.

### Example 1: Hole transport layer including Al₂O₃ and Spiro-OMeTAD

### Example 1-1: Hole transport layer including 0.5 wt % of Al₂O₃

The first electrode that was used was FTO glass (HS Technologies, Resistivity L<8Ω) etched using zinc powder and 2 M hydrochloric acid, after which sonication was performed for 10 min using deionized water (DI water), ethanol, acetone and isopropyl alcohol (IPA). Thereafter, UV ozone treatment was carried out for 15 min, thus removing organic residue.

An electron transport layer was formed of SnO₂ and manufactured as follows. Specifically, a SnO₂ precursor solution, obtained by dissolving 0.1 M SnCl₂.H₂O in 5 mL of ethanol, was applied through spin coating at 2,000 rpm for 30 sec on the first electrode, and then heat treatment was performed at 180° C. for 1 hr, thus forming a SnO₂ electron transport layer having a thickness of about 30 to 50 nm.

A mixed solution, obtained by dissolving 1 M NH₂CH═NH₂I (formamidinium iodide, FAI), 1.1 M PbI₂, 0.2 M CH₃NH₃Br (methylamine bromide, MABr), and 0.22 M PbBr₂ in 1 mL of a solution composed of dimethylformamide (DMF) and dimethylsulfoxide (DMSO) at a volume ratio of 4:1, was mixed at a volume ratio of 95:5 with a 1.5 M CsI solution in a dimethylsulfoxide solvent, thus preparing a perovskite precursor solution of Cs_{0.05}(FAPbI₃)_{0.79}(MAPbBr₃)_{0.16}.

The perovskite precursor solution was applied through spin coating at 1,000 rpm for 10 sec and then at 6,000 rpm for 20 sec on the electron transport layer in a nitrogen-filled glove box. 5 sec before termination of spin coating, 500 μL of chlorobenzene was sprayed thereto, followed by heat treatment at 100° C. for 1 hr, thus forming a photoactive layer having a perovskite structure and a thickness of about 500 nm.

An Al₂O₃ inorganic structure was manufactured through dynamic spin coating at 5,000 rpm for 40 sec using a 0.5 wt % aluminum oxide (Al₂O₃) solution dispersed in isopropyl alcohol.

A mixed solution was prepared by dissolving 72.3 mg of Spiro-OMeTAD as a hole transport organic material, and, as dopants, 27.8 μL of 4-tert-butyl pyridine (tBP), 17.8 μL of Li-TFSI and 3 mg of Co(II) PF₆ in chlorobenzene. This mixed solution was applied through spin coating at 5,000 rpm for 30 sec on the Al₂O₃ inorganic structure, thus forming a hole transport layer.

Subsequently, an Au electrode was deposited to a thickness of about 100 nm in a vacuum chamber having a vacuum level of 10⁷ torr or less, thereby manufacturing a perovskite solar cell.

### Example 1-2: Hole Transport Layer Including 1.0 wt % of Al₂O₃

A perovskite solar cell was manufactured in the same manner as in Example 1-1, with the exception that, in the hole transport layer, the inorganic structure was manufactured using a 1.0 wt % aluminum oxide (Al₂O₃) solution dispersed in isopropyl alcohol, rather than manufacturing the inorganic structure using the 0.5 wt % aluminum oxide (Al₂O₃) solution dispersed in isopropyl alcohol.

### Example 1-3: Hole Transport Layer Including 1.5 wt % of Al₂O₃

A perovskite solar cell was manufactured in the same manner as in Example 1-1, with the exception that, in the hole transport layer, the inorganic structure was manufactured using a 1.5 wt % aluminum oxide (Al₂O₃) solution dispersed in isopropyl alcohol, rather than manufacturing the inorganic structure using the 0.5 wt % aluminum oxide (Al₂O₃) solution dispersed in isopropyl alcohol.

### Example 2: Hole Transport Layer Including MgO and Spiro-OMeTAD

### Example 2-1: Hole Transport Layer Including 0.5 wt % of MgO

A perovskite solar cell was manufactured in the same manner as in Example 1-1, with the exception that, in the hole transport layer, the inorganic structure was manufactured using a 0.5 wt % magnesium oxide (MgO) solution dispersed in isopropyl alcohol, rather than manufacturing the inorganic structure using the 0.5 wt % aluminum oxide (Al₂O₃) solution dispersed in isopropyl alcohol.

### Example 2-2: Hole Transport Layer Including 1.0 wt % of MgO

A perovskite solar cell was manufactured in the same manner as in Example 1-1, with the exception that, in the hole transport layer, the inorganic structure was manufactured using a 1.0 wt % magnesium oxide (MgO) solution dispersed in isopropyl alcohol, rather than manufacturing the inorganic structure using the 0.5 wt % aluminum oxide (Al₂O₃) solution dispersed in isopropyl alcohol.

### Example 2-3: Hole Transport Layer Including 1.5 wt % of MgO

A perovskite solar cell was manufactured in the same manner as in Example 1-1, with the exception that, in the hole transport layer, the inorganic structure was manufactured using a 1.5 wt % magnesium oxide (MgO) solution dispersed in isopropyl alcohol, rather than manufacturing the inorganic structure using the 0.5 wt % aluminum oxide (Al₂O₃) solution dispersed in isopropyl alcohol.

### Example 3: Hole Transport Layer Including BN and Spiro-OMeTAD

### Example 3-1: Hole Transport Layer Including 0.5 wt % of BN

A perovskite solar cell was manufactured in the same manner as in Example 1-1, with the exception that, in the hole transport layer, the inorganic structure was manufactured using a 0.5 wt % boron nitride (BN) solution dispersed in isopropyl alcohol, rather than manufacturing the inorganic structure using the 0.5 wt % aluminum oxide (Al₂O₃) solution dispersed in isopropyl alcohol.

### Example 3-2: Hole Transport Layer Including 1.0 wt % of BN

A perovskite solar cell was manufactured in the same manner as in Example 1-1, with the exception that, in the hole transport layer, the inorganic structure was manufactured using a 1.0 wt % boron nitride (BN) solution dispersed in isopropyl alcohol, rather than manufacturing the inorganic structure using the 0.5 wt % aluminum oxide (Al₂O₃) solution dispersed in isopropyl alcohol.

### Example 3-3: Hole Transport Layer Including 1.5 wt % of BN

A perovskite solar cell was manufactured in the same manner as in Example 1-1, with the exception that, in the hole transport layer, the inorganic structure was manufactured using a 1.5 wt % boron nitride (BN) solution dispersed in isopropyl alcohol, rather than manufacturing the inorganic structure using the 0.5 wt % aluminum oxide (Al₂O₃) solution dispersed in isopropyl alcohol.

### Example 4: Hole Transport Layer Including AlN and Spiro-OMeTAD

### Example 4-1: Hole Transport Layer Including 0.5 wt % of AlN

A perovskite solar cell was manufactured in the same manner as in Example 1-1, with the exception that, in the hole transport layer, the inorganic structure was manufactured using a 0.5 wt % aluminum nitride (AlN) solution dispersed in isopropyl alcohol, rather than manufacturing the inorganic structure using the 0.5 wt % aluminum oxide (Al₂O₃) solution dispersed in isopropyl alcohol.

### Example 4-2: Hole Transport Layer Including 1.0 wt % of AlN

A perovskite solar cell was manufactured in the same manner as in Example 1-1, with the exception that, in the hole transport layer, the inorganic structure was manufactured using a 1.0 wt % aluminum nitride (AlN) solution dispersed in isopropyl alcohol, rather than manufacturing the inorganic structure using the 0.5 wt % aluminum oxide (Al₂O₃) solution dispersed in isopropyl alcohol.

### Example 4-2: Hole Transport Layer Including 1.5 wt % of AlN

A perovskite solar cell was manufactured in the same manner as in Example 1-1, with the exception that, in the hole transport layer, the inorganic structure was manufactured using a 1.5 wt % aluminum nitride (AlN) solution dispersed in isopropyl alcohol, rather than manufacturing the inorganic structure using the 0.5 wt % aluminum oxide (Al₂O₃) solution dispersed in isopropyl alcohol.

### Comparative Example 1

A perovskite solar cell was manufactured in the same manner as in Example 1-1, with the exception that the inorganic structure was not formed on the photoactive layer. Thus, the perovskite solar cell included a dopant-doped Spiro-OMeTAD as the hole transport layer.

### Test Examples

### Test Example 1: Comparison of Temperature Elevation of Each Layer of Perovskite Solar Cell

FIG. 2 shows the temperature over time of each layer of a conventional perovskite solar cell upon light irradiation.

With reference to FIG. 2, the layer having the highest temperature inside the device of the perovskite solar cell was confirmed, and the perovskite layer (photoactive layer) exhibited the highest temperature at any given time.

Therefore, it can be confirmed that heat conduction occurred from the perovskite layer (photoactive layer) to the other layer.

### Test Example 2: Change in Thermal Conductivity of Hole Transport Layer Depending on Type and Amount of Inorganic Structure

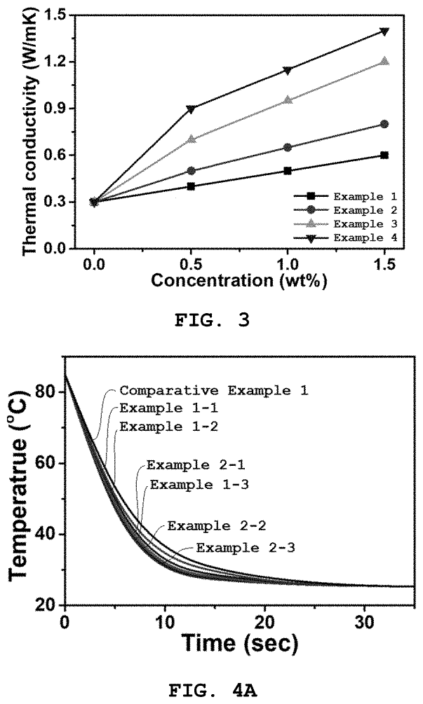

FIG. 3 shows the thermal conductivity of the hole transport layer in the perovskite solar cells manufactured in Examples 1-1 to 4-3, and the thermal conductivity depending on the type of the inorganic structure that was used is summarized in Table 1 below.

TABLE 1

| | | Thermal conductivity |
|---|---|---|
| Classification | Type of inorganic structure | [W/mK] |
| Example 1 | Aluminum oxide (Al₂O₃) | 20 |
| Example 2 | Magnesium oxide (MgO) | 60 |
| Example 3 | Boron nitride (BN) | 120 |
| Example 4 | Aluminum nitride (AlN) | 180 |
| Comparative | — | 0.3 |
| Example 1 | | |

As is apparent from FIG. 3 and Table 1, the inorganic structure was included in the hole transport layer and thus the thermal conductivity of the hole transport layer was increased. Moreover, as the thermal conductivity of the inorganic structure was higher, the thermal conductivity of the hole transport layer was further increased, based on which it is considered that the use of such a hole transport layer in a solar cell will facilitate heat dissipation from the device.

### Test Example 3: Comparison of Cooling Rate of Device Depending on Type and Amount of Inorganic Structure

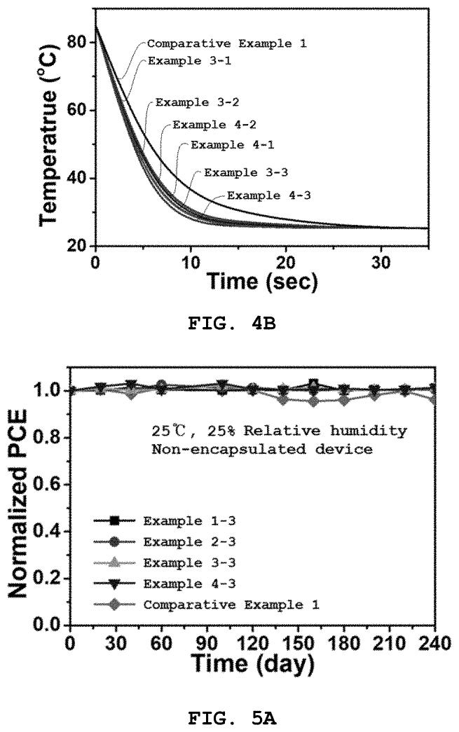

FIG. 4A shows the results of comparison of the cooling rate of the hole transport layer in the perovskite solar cells of Examples 1-1 to 2-3 and Comparative Example 1, and FIG. 4B shows the results of comparison of the cooling rate of the hole transport layer in the perovskite solar cells of Examples 3-1 to 4-3 and Comparative Example 1.

Specifically, in order to compare the cooling rates, the device was initially heated on a hot plate at 85° C., and after reaching the corresponding temperature, the device was transferred onto a cooling plate at 25° C. As such, the temperature of each device was compared over time.

With reference to FIGS. 4A and 4B, it can be seen that the thermal conductivity of the hole transport layer and the cooling rate thereof are proportional, and the use of the hole transport layer having high thermal conductivity is expected to improve the stability of perovskite solar cells.

### Test Example 4: Measurement of Operating Efficiency of Perovskite Solar Cell

Table 2 below shows the characteristics of perovskite solar cells manufactured in Examples 1-3, 2-3, 3-3 and 4-3 and Comparative Example 1.

TABLE 2

| | | Optical | | | |
|---|---|---|---|---|---|
| | Type of | short- | Optical | | |
| | inorganic | circuit | open- | | |
| | structure of | current | circuit | | Photoelectric |
| | hole | density | voltage | Fill | conversion |
| | transport | [J_{sc}, | [V_{oc}, | factor | efficiency |
| Classification | layer | mA/cm²] | V] | [FF] | (%) |
| Example 1-3 | Aluminum | 22.7 | 1.19 | 78.8 | 21.2 |
| | oxide | | | | |
| | (Al₂O₃) | | | | |
| Example 2-3 | Magnesium | 22.7 | 1.19 | 77.6 | 20.86 |
| | oxide (MgO) | | | | |
| Example 3-3 | Boron nitride | 22.0 | 1.09 | 69.3 | 16.53 |
| | (BN) | | | | |
| Example 4-3 | Aluminum | 22.0 | 1.06 | 70.6 | 16.42 |
| | nitride (AlN) | | | | |
| Comparative | — | 23.8 | 1.14 | 78.3 | 21.3 |
| Example 1 | | | | | |

As is apparent from Table 2, in the hole transport layers including aluminum oxide and magnesium oxide of Example 1-3 and Example 2-3, high efficiency was more effectively maintained than in the case of Comparative Example 1, using Spiro-OMeTAD alone.

In contrast, the use of boron nitride and aluminum nitride as in Example 3-3 and Example 4-3 deteriorated device performance. This is because boron nitride and aluminum nitride, which have a relatively large nanoparticle size (>50 nm), are not uniformly dispersed in the hole transport layer, thus interfering with charge flow.

### Test Example 5: Evaluation of Stability of Perovskite Solar Cell

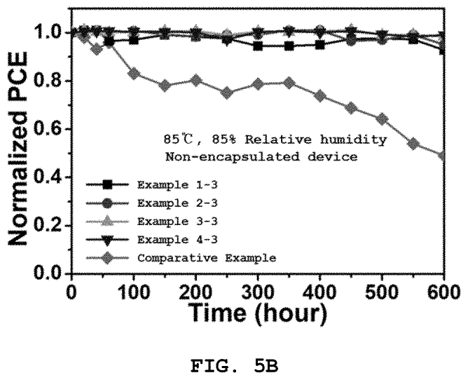

FIG. 5A shows the stability over time of the perovskite solar cells manufactured in Examples 1-3, 2-3, 3-3 and 4-3 and Comparative Example 1 when not encapsulated at 25° C. and 25% relative humidity, and FIG. 5B shows the stability over time of the perovskite solar cells manufactured in Examples 1-3, 2-3, 3-3 and 4-3 and Comparative Example 1 when not encapsulated at 85° C. and 85% relative humidity.

With reference to FIGS. 5A and 5B, all devices exhibited superior stability at 25° C. and 25% relative humidity, and there was no significant difference in stability. On the other hand, the difference was remarkable under harsh conditions of 85° C. and 85% relative humidity, and the solar cells of Examples 1-3, 2-3, 3-3 and 4-3 exhibited high stability even under harsh conditions because the hole transport layer included the inorganic structure. This is because the hole transport layer includes the inorganic structure having high thermal conductivity, thereby exhibiting a superior heat dissipation effect and effectively blocking the introduction of external substances (water and oxygen), indicating that the hole transport layer of the present invention provides much improved stability.

The scope of the invention is defined by the claims below rather than the aforementioned detailed description, and all changes or modified forms that are capable of being derived from the meaning, range, and equivalent concepts of the appended claims should be construed as being included in the scope of the present invention.

What is claimed is:

1. A hole transport layer, comprising:
a thermally conductive inorganic structure comprising a plurality of nanoparticles and having pores surrounded by the nanoparticles; and
a hole transport organic material located in the pores,
wherein the nanoparticles comprise at least one inorganic material selected from the group consisting of a metal oxide and a metal nitride.

2. The hole transport layer of claim 1, wherein a portion of the plurality of nanoparticles is located on a top surface of the hole transport layer,
a further portion of the plurality of nanoparticles is located on a bottom surface of the hole transport layer, and
still a further portion of the plurality of nanoparticles forms a connection between the nanoparticles located on the top surface and the nanoparticles located on the bottom surface.

3. The hole transport layer of claim 1, wherein the connection is a contact connection or a thermal connection.

4. The hole transport layer of claim 1, wherein a portion of the hole transport organic material is located on a top surface of the hole transport layer,
a further portion of the hole transport organic material is located on a bottom surface of the hole transport layer, and
still a further portion of the hole transport organic material forms a connection between the hole transport organic material located on the top surface and the hole transport organic material located on the bottom surface.

5. The hole transport layer of claim 4, wherein the connection is a contact connection or a thermal connection.

6. The hole transport layer of claim 1, wherein the nanoparticles have a diameter (d_{NP}) of 10 to 50 nm, and a ratio (d_{HTL}/d_{NP}) of a thickness (d_{HTL}) of the hole transport layer relative to a diameter (d_{NP}) of the nanoparticles is 3 to 5.

7. The hole transport layer of claim 1, wherein the inorganic material has a HOMO (highest occupied molecular orbital) energy level less than −5.6 eV and a LUMO (lowest unoccupied molecular orbital) energy level greater than −3.9 eV.

8. The hole transport layer of claim 1, wherein the inorganic material comprises at least one selected from the group consisting of Al₂O₃, MgO, BN, AlN, SiO₂, Si₃N₄, and SiC.

9. The hole transport layer of claim 1, wherein the hole transport organic material comprises at least one selected from the group consisting of 2,2′,7,7′-tetrakis-(N,N-di-4-methoxyphenylamino)-9,9′-spirobifluorene (Spiro-OMeTAD), poly[bis(4-phenyl)(2,4,6-trimethylphenyl)amine] (PTAA), poly(3-hexylthiophene-2,5-diyl) (P3HT), poly(3-alkylthiophene) (P3AT), poly(3-octylthiophene-2,5-diyl) (P3OT), poly(3,4-ethylenedioxythiophene)-poly(styrenesulfonate) (PEDOT:PSS), poly{4,7-bis(5-bromothiophen-2-yl)-5-(decyloxy)-6-ethoxybenzo[c][1,2,5]thiadiazole} (PBT), poly{(4,8-bis((2-butyloctyl)oxy)benzo[1,2-b:4,5-b′]dithiophene-2,6-diyl)bis(trimethylstannane)} (PBDT), and poly(BT)-(BDT).

10. The hole transport layer of claim 1, wherein the hole transport organic material is doped with a dopant, and the dopant comprises at least one selected from the group consisting of Li-TFSI, Co(II) PF₆, 4-tert-butyl pyridine (tBP), AgTFSI, and CuI.

11. A perovskite solar cell, comprising:
a first electrode;
an electron transport layer formed on the first electrode;
a photoactive layer formed on the electron transport layer and comprising a perovskite material;
the hole transport layer of claim 1 formed on the photoactive layer; and
a second electrode formed on the hole transport layer.

12. The perovskite solar cell of claim 11, wherein the first electrode comprises at least one selected from the group consisting of fluorine tin oxide (FTC), indium tin oxide (ITO), indium zinc oxide (IZO), indium zinc tin oxide (IZTO), aluminum zinc oxide (AZO), indium-tin-oxide/silver/indium-tin-oxide (ITO-Ag-ITO), indium-zinc-oxide/silver/indium-zinc-oxide (IZO-Ag-IZO), indium-zinc-tin-oxide/silver/indium-zinc-tin-oxide (IZTO-Ag-IZTO), and aluminum-zinc-oxide/silver/aluminum-zinc-oxide (AZO-Ag-AZO).

13. The perovskite solar cell of claim 11, wherein the electron transport layer comprises at least one selected from the group consisting of SnO₂, ZnO, TiO₂, Al₂O₃, MgO, Fe₂O₃, WO₃, In₂O₃, BaTiO₃, BaSnO₃, and ZrO₃.

14. The perovskite solar cell of claim 11, wherein the perovskite material comprises at least one selected from the group consisting of CH₃NH₃PbI₃₋ₓClₓ (in which x is a real number satisfying 0≤x≤3), CH₃NH₃PbI₃₋ₓBrₓ (in which x is a real number satisfying 0≤x≤3), CH₃NH₃PbCl₃₋ₓBrₓ (in which x is a real number satisfying 0≤x≤3), CH₃NH₃PbI₃₋ₓFₓ, (in which x is a real number satisfying 0≤x≤3), NH₂CH═NH₂PbI₃₋ₓClₓ (in which x is a real number satisfying 0≤x≤3), NH₂CH═NH₂PbI₃₋ₓBrₓ (in which x is a real number satisfying 0≤x≤3), NH₂CH═NH₂PbCl₃₋ₓBrₓ (in which x is a real number satisfying 0≤x≤3), NH₂CH═NH₂PbI₃₋ₓFₓ, (in which x is a real number satisfying 0≤x≤3), and Csₖ(NH₂CH═NH₂PbI₃)₍₁₋ₖ₋ₓ₎ (CH₃NH₃PbBr₃)ₓ (in which k is a real number satisfying 0≤k·13.3 and x is a real number satisfying 0≤x≤1−k).

15. The perovskite solar cell of claim 11, wherein the second electrode comprises at least one selected from the group consisting of Ag, Au, Al, Fe, Cu, Cr, W, Mo, Zn, Ni, Pt, Pd, Co, In, Mn, Si, Ta, Ti, Sn, Pb, V, Ru, Ir, Zr, Rh, and Mg.

16. A method of manufacturing a hole transport layer, comprising:
(1) forming a thermally conductive inorganic structure comprising a plurality of nanoparticles and having pores surrounded by the nanoparticles by performing coating with a solution comprising the nanoparticles and performing drying; and
(2) forming a hole transport layer comprising a hole transport organic material located in the pores by performing coating with a solution comprising the hole transport organic material on the thermally conductive inorganic structure and performing drying,
wherein the nanoparticles comprise at least one inorganic material selected from the group consisting of a metal oxide and a metal nitride.

17. The method of claim 16, wherein the coating in step (2) enables the pores to be impregnated with the solution comprising the hole transport organic material.

18. The method of claim 16, wherein the coating in steps (1) and (2) is performed through at least one process selected from the group consisting of spin coating, spray coating, chemical vapor deposition, and atomic layer deposition.

19. The method of claim 16, wherein, in step (1), the solution comprising the nanoparticles comprises 0.1 to 3 wt % of the nanoparticles.

20. A method of manufacturing a perovskite solar cell, comprising:
(a) forming an electron transport layer on a first electrode;
(b) performing coating with a solution comprising a perovskite precursor on the electron transport layer;
(c) forming a photoactive layer comprising a perovskite material by heat-treating a perovskite precursor coating layer formed on the electron transport layer;
(d) forming a thermally conductive inorganic structure comprising a plurality of nanoparticles and having pores surrounded by the nanoparticles by performing coating with a solution comprising the nanoparticles on the photoactive layer;
(e) forming a hole transport layer comprising a hole transport organic material located in the pores by performing coating with a solution comprising the hole transport organic material on the thermally conductive inorganic structure; and
(f) forming a second electrode on the hole transport layer,
wherein the nanoparticles comprise at least one inorganic material selected from the group consisting of a metal oxide and a metal nitride.
